(19) United States
(12) Patent Application Publication
(10) Pub. No.: US 2011/0291287 A1
(43) Pub. Date: Dec. 1, 2011

(54) THROUGH-SILICON VIAS WITH LOW PARASITIC CAPACITANCE

(75) Inventors: Paul Y. Wu, Saratoga, CA (US); Suresh Ramalingam, Fremont, CA (US); Namhoon Kim, Mt. View, CA (US)

(73) Assignee: XILINX, INC., San Jose, CA (US)

(21) Appl. No.: 12/786,931

(22) Filed: May 25, 2010

(51) Int. Cl. H01L 23/48; H01L 21/768

(52) U.S. Cl. 257/774; 438/675; 257/E23.011; 257/E21.597

(57) ABSTRACT

A device has a silicon substrate with a via extending from a first surface of the silicon substrate having a conductor portion. A first dielectric portion surrounds the conductor portion. A second dielectric portion is disposed between a first silicon portion and the silicon substrate.

### FIELD OF THE INVENTION

An embodiment of the invention relates generally to integrated circuits, and more particularly to techniques for fabricating through-silicon vias for high-frequency applications.

### BACKGROUND

For a given node technology, increasing integrated circuit (IC) size typically increases the functionality that can be included on a chip. Unfortunately, defects often scale with chip area. A large chip is more likely to incorporate a defect than is a smaller chip. Defects affect yield, and yield loss often increases with increasing chip size. Various techniques have been developed to provide large ICs at desirable yield levels.

One approach to providing large ICs is to construct a large IC out of multiple smaller ICs (dice) on a silicon interposer or to stack IC chips using through-silicon via (TSV) techniques. A silicon interposer is essentially a substrate that the dice are flip-chip bonded to after the silicon interposer has been processed to provide metal wiring and contacts. A silicon interposer typically has several patterned metal layers and intervening insulating layers connected to TSVs. Multiple IC dice are physically and electrically connected to the interposer with micro-bump arrays.

Stacked IC chips use TSV techniques to allow electrical connections to both sides of the parent IC chip. For example, one side (e.g., frontside) of the parent chip is bonded to a printed wiring board, package base, or other substrate, such as with a ball grid array, and the other side has a micro-bump or other bonding technique that a second, frequently smaller, chip(s) is bonded to. TSVs extend from the active portion of the first IC to the backside of the IC, and a microbump array or bonding pads are fabricated on the backside.

Many TSVs carry low-frequency signals or DC, such as a bias voltage or a ground return, and conventional TSVs are adequate for these applications. However, ICs that have radio-frequency (RF) or other high-frequency ports (e.g., pins or pads), or critical digital paths, such as a digital path with fast (e.g., 200 ps or less) rise or fall time, the high-frequency performance of a conventional TSV may be the limiting factor in the high-frequency or critical data path. For example, a high capacitance TSV may degrade a high-frequency signal, degrade rise/fall times of a digital signal, increase cross-talk between a signal on another TSV, or increase noise injection. Furthermore, variations in capacitance in TSVs can cause undesirable variations in device performance, whether the capacitance variations are between TSVs on a single IC or interposer, or are between TSVs on different parts.

Techniques for reducing TSV capacitance or capacitance variation are desirable.

### SUMMARY

A device according to an embodiment has a via extending from a first surface of a silicon substrate. The via has a conductor portion surrounded by a first dielectric portion. A first silicon portion is next to the first dielectric portion, and a second dielectric portion is between the first silicon portion and the silicon substrate. In a particular embodiment, the conductor portion is cylindrical, the first silicon portion surrounds the first dielectric portion, and the second dielectric portion surrounds the first substrate portion. In a further embodiment, the via includes a second silicon portion surrounding the second dielectric portion, and a third dielectric portion surrounding the second silicon portion.

In a particular embodiment, the via extends from the first surface of the silicon substrate through the silicon substrate to a second surface of the silicon substrate. In a further embodiment, a contact pad electrically connected to the conductor portion extends over the first dielectric portion and the first silicon portion, and at least partially over the second dielectric portion.

In a particular embodiment, the first dielectric portion is silicon oxide and the second dielectric portion is silicon oxide. In a further embodiment, both the first dielectric portion and the second dielectric portion are thermally grown silicon dioxide. In a yet further embodiment, a passivating oxide layer is concurrently grown on the top surface of the silicon wafer.

In a particular embodiment, the first dielectric portion has a first dielectric thickness and the second dielectric portion has a second dielectric thickness, the second dielectric thickness being not greater than twice the first dielectric thickness.

In a further embodiment, a first IC is mounted on the silicon substrate and has a signal pin electrically coupled to the via. In a particular embodiment, the IC comprises an FPGA, and in a more particular embodiment, the signal pin is a high-frequency signal pin or a high-speed digital data pin.

In another embodiment, a second IC is fabricated in the silicon substrate and the via connects the signal pin of the first IC to an active portion of the second IC. In a particular embodiment, the second IC comprises a field-programmable gate array. In a further embodiment, the second IC has a second signal pin electrically connected to a second via having a second conductor portion, a dielectric liner portion surrounding the conductor portion, a first floating silicon portion, and a dielectric ring surrounding the first floating silicon portion disposed between the first floating silicon portion and the silicon substrate.

In a particular embodiment, the silicon substrate is a silicon interposer and a capacitance between the conductor portion and the silicon substrate is not greater than 50 fF. In a particular embodiment, the silicon substrate has a bulk resistivity less than 20 Ohm-cm for use as an IC substrate or active interposer substrate.

In a particular embodiment, an interposer has a silicon substrate with a via formed within the silicon substrate. The via includes a first conductor portion with a first dielectric liner surrounding the first conductor portion. A first silicon portion surrounds the first conductor portion and a first dielectric ring surrounds the first silicon portion. A second silicon portion surrounds the first dielectric ring, and a second dielectric ring surrounds the second silicon portion.

In another embodiment, a via is fabricated in a silicon wafer by defining an etch resist pattern on a surface of the silicon wafer. A conductor pocket and at least one dielectric ring pocket in the silicon wafer separated from the conductor pocket by a silicon portion are etched in the silicon wafer. Oxide is formed on a sidewall of the conductor pocket to provide a lined conductor pocket and on sidewalls of the dielectric ring pocket. A conductor is then formed in the lined conductor pocket. In a particular embodiment, forming oxide on sidewalls of the dielectric ring pocket fills the dielectric ring pocket to form a dielectric ring surrounding the silicon portion. In an alternative embodiment, oxide is grown on the sidewalls of the dielectric ring pocket to partially fill the pocket, and the remainder of the dielectric ring pocket is filled with other dielectric material. In a further embodiment, the silicon wafer is backlapped to expose the conductor on a backside of the silicon wafer.

After the step of forming the conductor, a contact pad parallel to the surface extending from the conductor at least partially over the dielectric ring is optionally formed in a further embodiment.

In a particular embodiment, defining the etch resist pattern defines a concentric dielectric ring window around a conductor window, the concentric dielectric ring window having a width not greater than twice a thickness of oxide formed on the sidewall of the conductor pocket. In a further embodiment, defining the etch resist pattern further defines a second concentric dielectric ring window around the concentric dielectric ring window. The etching leaves a first concentric silicon portion between the conductor pocket and the concentric dielectric ring pocket and a second concentric silicon portion between the concentric dielectric ring pocket and a second concentric dielectric ring pocket.

### BRIEF DESCRIPTION OF THE DRAWINGS

FIG. 1 is a cross section of a composite IC with TSVs in an interposer according to an embodiment.

FIG. 2 is a cross section of a composite IC having stacked IC chips with TSVs according to an embodiment.

FIG. 3A is a plan view of a TSV according to an embodiment.

FIG. 3B is a cross section of the TSV of FIG. 3A.

FIG. 3C is a cross section of the TSV of FIG. 3B with a contact pad formed over the TSV.

FIG. 4A is a plan view of a TSV according to another embodiment.

FIG. 4B is a cross section of the TSV of FIG. 4A.

FIG. 5A is a cross section of a portion of a silicon wafer partially processed to form a TSV in accordance with an embodiment.

FIG. 5B is a cross section of the portion of the silicon wafer of FIG. 5A after an etch process.

FIG. 5C is a cross section of the portion of the silicon wafer of FIG. 5B after an oxide growth process.

FIG. 5D is a cross section of the portion of the silicon wafer of FIG. 5C after a metallization process.

FIG. 6 is a plan view of a portion of a TSV array according to an embodiment.

FIG. 7 is a flow chart of a process of fabricating a TSV according to an embodiment.

FIG. 8 is a plan view of an FPGA suitable for use with embodiments.

### DETAILED DESCRIPTION

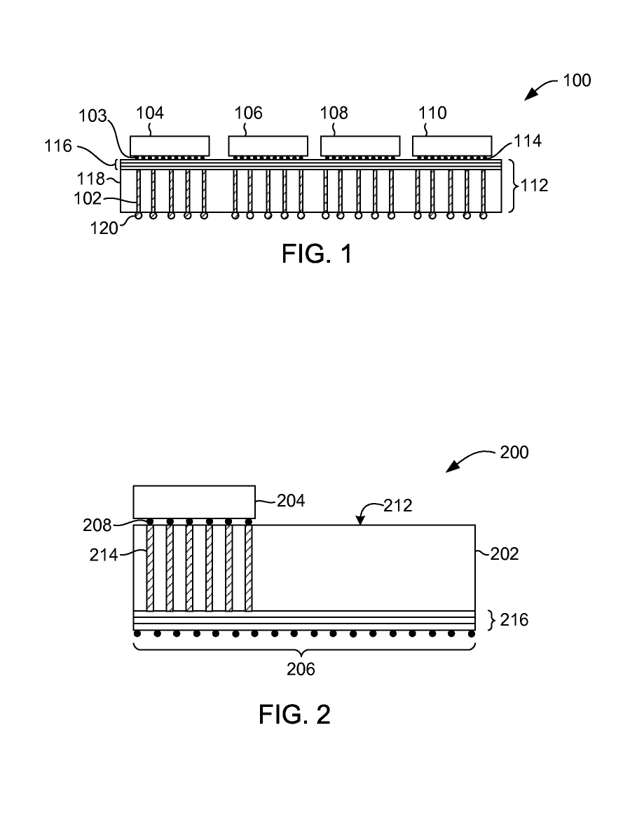

FIG. 1 is a cross section of a composite IC 100 with TSVs 102 according to an embodiment in an interposer 112. Four IC chips 104, 106, 108, 110 are mounted on the interposer 112. The IC chips 104, 106, 108, 110 are flip-chip bonded to the interposer 112, making electrical connection to the interposer 112 through conductive microbump arrays 114. For example, the IC chips are fabricated with C4 or microbump array, which electrically and mechanically connect each IC chip to corresponding micro-contact arrays on the interposer. Other types of contacts, contact arrays, and bonding techniques are alternatively used. Other features and structures, such as underfill or molding compound, are omitted for purposes of illustration.

The interposer 112 has patterned metal layers 116 fabricated on a silicon wafer portion 118. In a particular example, the silicon wafer portion 118 is a portion of a silicon wafer similar to those used in IC fabrication and the interposer is an active interposer (i.e., the interposer includes electronic devices in addition to patterned metal layers). The patterned metal layers 116 may be formed using deposition and photolithographic techniques similar to those used for IC fabrication. For example, if an IC fabrication process flow (e.g., a 90 nm node technology) defines several patterned metal layers on an IC wafer (commonly called the backend fabrication process), processes similar to those used to define the upper metal layers of the IC may be used to fabricate the patterned metal layers on the interposer wafer. Interposers typically have 1 to 4 patterned metal layers separated by intervening dielectric layers and interconnected using conductive vias, as is well known in the art of thin film, damascene or dual damascene processing.

The interposer 112 translates the fine pitch of the IC contacts on the topside of the interposer to a less fine pitch on the backside. In particular examples, the topside of the interposer has about 20,000 to about 60,000 microbump contacts, and about 10,000 to about 30,000 TSVs, depending on the size of the composite IC, the number and type of ICs mounted on the interposer, and other factors. In a particular example, the microbumps are at a 45 micron pitch and the TSVs are bumped 120 to form a bump array having a pitch of about 180 microns to about 200 microns. At least one of the TSVs is fabricated according to an embodiment of the invention. In some embodiments, several TSVs (e.g., the TSVs carrying high-frequency analog signals or high-speed digital signals) are fabricated according to one or more embodiments to couple the high-speed or high-frequency signals to a corresponding high-frequency port (i.e., bump or contact) on an IC chip. Other TSVs (e.g., TSVs carrying DC bias, ground current return, or low-frequency signals) are optionally conventional TSVs. Those of skill in the art of composite ICs appreciate that FIG. 1 is simplified for purposes of illustration, and specific dimensions and numbers are merely exemplary. In a particular embodiment, pin 103 of IC 104 is a high-frequency signal pin, and is connected to TSV 102, which is a TSV having one or more dielectric rings according to an embodiment.

FIG. 2 is a cross section of a composite IC 200 having stacked IC chips 202, 204 with TSVs 214 according to an embodiment. For purposes of convenient discussion, the lower IC chip 202 will be referred to as an active interposer chip and the upper IC chip 204 as a stacked chip. The active interposer chip 202 has a first contact array (e.g., a ball grid array or a bump grid array) on the front side 206 of the active interposer chip 202 and a second contact array including signal pin 208 on the backside 212 of the active interposer chip 202, which in a particular embodiment is a high-frequency signal pin. A stacked chip 204 is electrically connected to the active interposer chip 202 through the second contact array 208. TSVs, including high-frequency TSV 214 according to an embodiment, extend from the active portion 216 of the active interposer chip 202 to the backside 212. One or more of the TSVs 214 is fabricated according to an embodiment (e.g., the TSVs carrying high-frequency analog signals or high-speed digital signals) and other TSVs are optionally conventional TSVs. In a particular embodiment, the active interposer chip 202 is a field-programmable gate array (FPGA) or other programmable IC. The stacked chip 204 is another FPGA, or alternatively a memory chip, a processor chip, or other IC chip. However, in other embodiments, stacked chip 204 is a non-programmable IC. Providing TSVs in an FPGA according to an embodiment is particularly desirable when connecting a high-speed or high-frequency port of the stacked chip 204 to the active interposer chip 202 because the lower parasitic capacitance of the TSV provides good signal transmission and low cross-coupling.

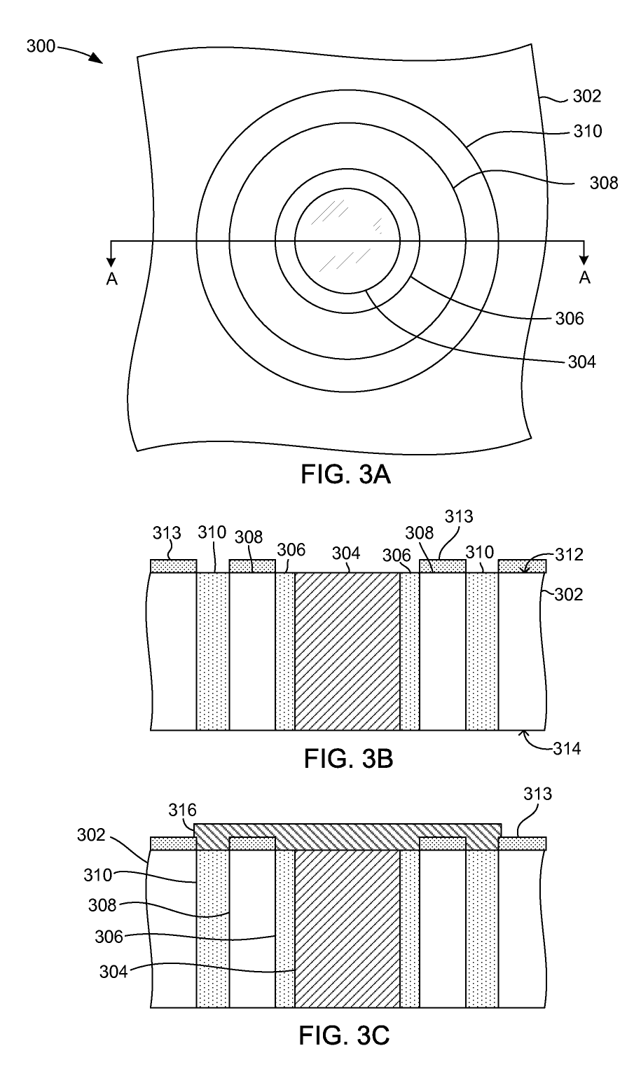

FIG. 3A is a plan view of a TSV 300 according to an embodiment. The TSV 300 is fabricated in a silicon wafer 302, such as a silicon wafer used in a silicon interposer or silicon IC process. The TSV 300 is a conductive via that has a conductor portion 304 surrounded by a first dielectric portion 306. The first dielectric portion 306 electrically isolates the conductor portion 304 from a first silicon portion 308. A second dielectric portion 310 separates the first silicon portion 308 from the silicon wafer 302 (bulk silicon). In a particular embodiment, conductor portion 304 includes plated metal, such as copper. Many techniques for forming conductors in vias are known in the art of IC fabrication and interposer fabrication. For example, the conductive portion is formed by sputtering a seed layer on the inner wall of the first dielectric portion 306, and then copper or other metal or metal alloy is plated to form the conductor portion. However, in other embodiments, other techniques are used to form conductor portion 304.

In a particular embodiment, the first dielectric portion 306 is grown silicon oxide that is grown from silicon previously of the first silicon portion 308. Similarly, the second dielectric portion 310 is grown silicon oxide that is grown from silicon previously of the first silicon portion 308 and the bulk silicon (wafer) 302. Alternative embodiments use other dielectric materials, such as spin-on dielectric precursors, or organic materials such as polyimide. In some embodiments, at least one of the dielectric portions uses composite dielectric material, such as a relatively thin liner of thermally grown oxide on the silicon walls, and a filler material of applied dielectric material. It is generally desirable that the dielectric material(s) used for the first and second dielectric portions have a relative dielectric constant(s) less than the relative dielectric constant of silicon.

FIG. 3B is a cross section of the TSV of FIG. 3A taken along section line A-A. The first dielectric portion 306 forms a cylinder that surrounds the conductor portion 304. As used herein, “surrounds” means that the major side (e.g., the cylindrical circumference) of the features are surrounded in a cylindrical or other fashion. The dielectric portion does not encapsulate (i.e., cover all surfaces) of the conductor, as it is desired to make electrical connection to the conductor. Similarly, the first silicon portion 308 forms a cylinder that surrounds first conductor portion 304, and the second dielectric portion 308 forms a cylinder that surrounds the first silicon portion 308. The TSV extends from a first side 312 to a second side 314 of the bulk silicon 302. A dielectric layer 313, commonly called a passivation layer, is formed on the wafer to passivate and isolate the bulk silicon 302. The dielectric layer can be, for example, a layer of deposited or grown silicon oxide, silicon nitride, or a polymer dielectric material such as polyimide.

FIG. 3C is a cross section of the TSV of FIG. 3B with a contact pad 316 formed over the TSV. The contact pad 316 will be attached to a solder bump or solder ball of a mating IC, or a solder bump or ball (not shown) will be formed on the contact pad 316. The contact pad 316 is electrically connected to the conductor portion 304, and capacitively couples to the first dielectric portion 306, the first silicon portion (silicon body) 308 and the second dielectric portion 310. The dielectric layer 313 electrically isolates the contact pad 316 from the bulk silicon 302. In an alternative embodiment, the larger contact pad extends over the bulk silicon of the wafer, and also capacitively couples to the bulk silicon, which is often at ground potential. In a particular embodiment, the silicon body 308 is electrically floating (i.e., is not electrically connected to other structures, other than capacitively through the associated dielectric layers).

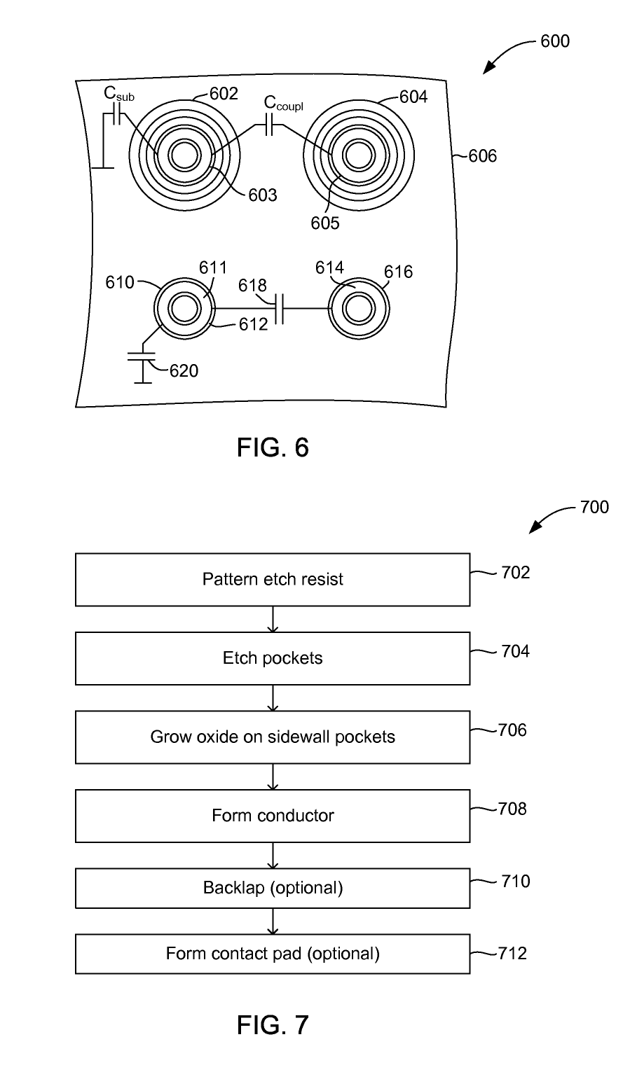

In a conventional TSV, bulk silicon extends from the dielectric liner layer (e.g., a layer similar to layer 306), and a similar contact pad would capacitively couple to the wafer (substrate) from the outer edge of the dielectric layer to the outer edge of the contact pad. Similarly, the conductor portion of a conventional TSV capacitively couples to the substrate through the relatively thin dielectric liner layer. This structure forms undesirable TSV-to-substrate capacitive coupling. Similarly, TSV-to-TSV capacitive coupling arises in TSV arrays (see, e.g., FIG. 6).

The second dielectric portion 310 electrically isolates the first silicon portion 308 from the bulk silicon and reduces the capacitive coupling between the conductor portion 304 of the TSV and silicon wafer 302, compared to a conventional TSV having only a dielectric liner layer separating the conductor from the bulk silicon, because the relative dielectric constant of silicon dioxide (εᵣ=4) or other dielectric material according to an embodiment is less than the dielectric constant of silicon (εᵣ=12), because the separation between the coupling electrodes (i.e., the conductive portion 304 and the bulk silicon 302) is increased (by the thickness of the second dielectric portion 310), and because the first silicon portion 308 basically forms an intermediate electrode in a series capacitance between the conductive portion 304 and the bulk silicon. The second dielectric portion 310 also reduces the capacitive coupling of the contact pad 316 to the bulk silicon 302 because of the reduced dielectric constant under the pad and because the capacitive coupling to the first silicon portion 308 is isolated from the bulk silicon (essentially forming series capacitances).

In a particular embodiment, the parasitic capacitance of a TSV according to an embodiment is less than 50 femto-Farads (fF) in a silicon wafer having a sheet resistivity of about 20 ohm-cm. A conventional TSV having a similarly sized conductor fabricated in the same silicon wafer has a parasitic capacitance of about 100 fF. A TSV having a parasitic capacitance of not more than 50 fF is desirable for use in conductive paths of analog signals 5 GHz or higher, and for use in conductive paths of digital signals having a rise or fall time of 200 ps or faster. In other embodiments, silicon wafers with lower sheet resistivity are used. For example, a TSV according to an embodiment in a silicon wafer having a sheet resistivity of about 1 ohm-cm has a parasitic capacitance of about 200 fF. In active TSVs, the resistivity of the wafer may be constrained by circuit requirements, thus embodiments are particularly desirable in embodiments where high-resistivity wafers are precluded.

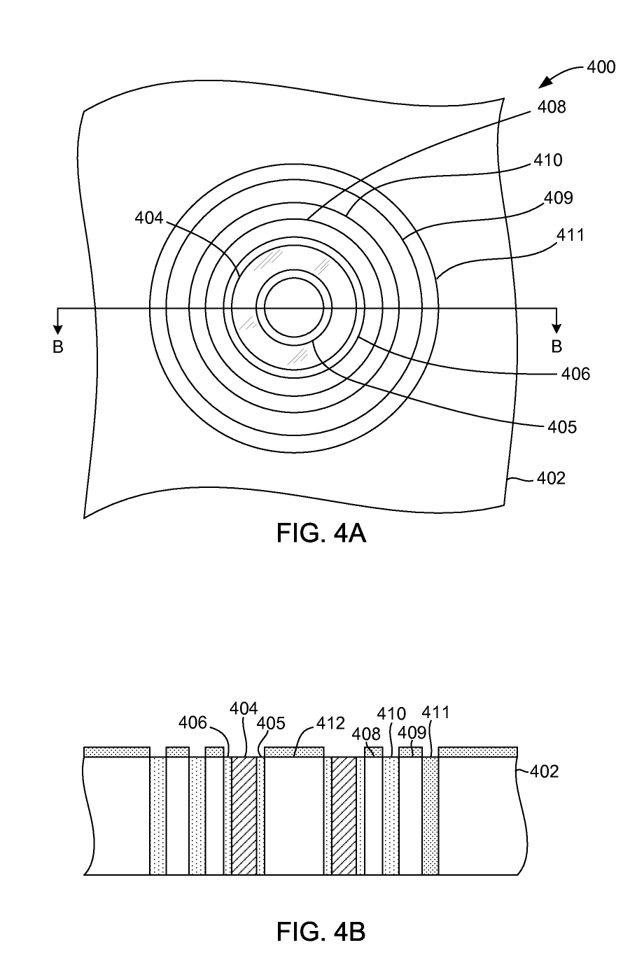

FIG. 4A is a plan view of a TSV 400 according to another embodiment. A conductive portion 404 has an annular, rather than solid, cross section (compare, FIG. 3A, ref. num. 304). Dielectric liner layers 405, 406 are formed, and the conductive portion 404 is sputtered, plated or otherwise formed. Annular cylinders of dielectric material 408, 409 surround the conductive portion 404 and intervening silicon portions 408, 409. The conductive portion 404 is separated from the bulk silicon by the outer dielectric liner layer 406, the first silicon portion 408, the first dielectric ring 410, the second silicon portion 409, and the second dielectric ring 411.

FIG. 4B is a cross section of the TSV of FIG. 4A taken along section line B-B. The conductive portion 404 is separated from the bulk silicon by the outer dielectric liner layer 406, the first silicon portion (first silicon body) 408, the first dielectric ring 410, the second silicon portion (second silicon body) 409, and the second dielectric ring 411. Inner dielectric line layer 405 separates the conductive portion 404 from a central silicon portion 412. In a particular embodiment, the central silicon portion 412 provides silicon during the oxide growth process that forms the inner dielectric liner layer 405. The central silicon portion 412 also reduces the mass of copper in the via (compared to a similarly sized solid copper conductor), and improves thermal matching and reduces copper protrusions without significantly affecting conductivity of the via. A passivation layer (not shown) is typically included for isolating contact pads (also not shown) from the silicon. In particular embodiments, both the first silicon body 408 and the second silicon body 409 are electrically floating in the finished device.

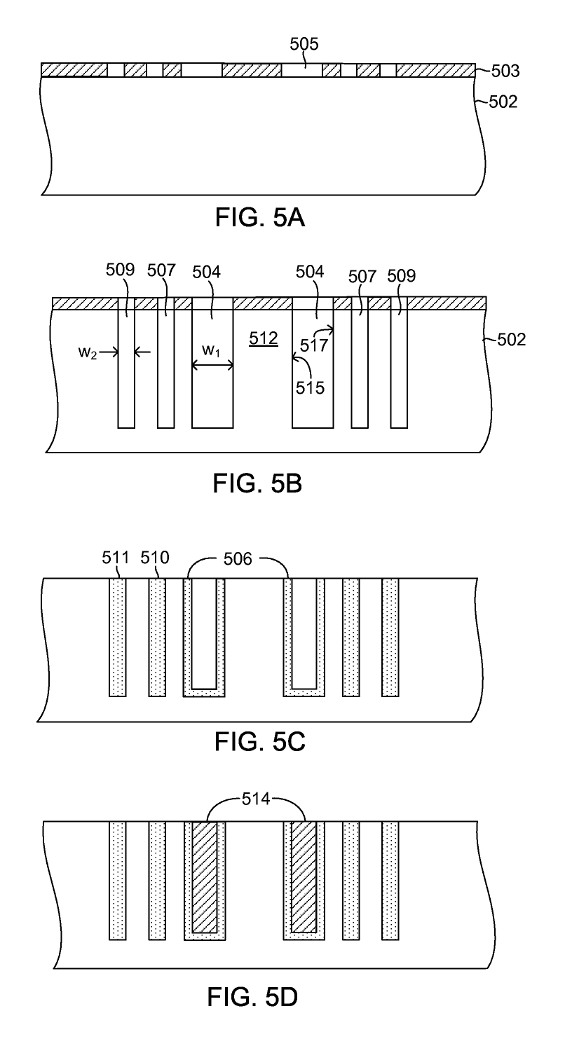

FIG. 5A is a cross section of a portion of a silicon wafer 502 partially processed to form a TSV in accordance with an embodiment. A layer of masking material (e.g., photoresist compatible a subsequent silicon etch process) 503 has been patterned to form windows 505 exposing silicon.

FIG. 5B is a cross section of the portion of the silicon wafer of FIG. 5A after an etch process. An etch process, such as a anisotropic etch process, has been used to remove silicon from the silicon wafer where the wafer is not protected by resist to form pockets 504, 507, 509. For purposes of convenient discussion, pocket 504 will be referred to as a conductor pocket, and pockets 507 and 509 will be referred to as dielectric ring pockets. In a plan view, the pockets would typically appear as concentric circles around the central silicon portion 512. The width w1 of conductor pocket 504, indicated by a double ended arrow, is sufficient to grow the liner oxide (see, FIG. 5C, ref. num. 506) on the sidewalls 515, 517 of the conductor pocket 504 to a desired thickness, and to fill with metal for the conductor portion. In a particular embodiment, the width w2 of dielectric ring pocket 509 is not greater than twice the thickness of the liner dielectric (see FIG. 5C, ref. num. 506) in an embodiment using grown silicon dioxide to fill pockets 507, 509, which in a particular embodiment is grown on the sidewalls of the dielectric ring pockets. Embodiments using other dielectric material, such as spun-on semiconductor dielectric resin or porous dielectric precursor optionally form pockets wider than twice the dielectric liner layer thickness. An alternative embodiment has a solid conductor (i.e., silicon 512 is omitted), and the conductor pocket only has one sidewall (e.g., sidewall 517).

FIG. 5C is a cross section of the portion of the silicon wafer of FIG. 5B after an oxide growth process. A dielectric liner layer 506 has been grown on the sidewalls of the pocket that will be filled with conductive material, and silicon oxide has grown to form dielectric rings 510, 511 (compare, FIG. 4A, ref. nums. 410, 411). Alternatively, an oxide layer is grown that forms the liner layer(s) and partially fills the dielectric ring pocket(s), and the remainder of the dielectric ring pocket(s) is filled with a different dielectric material, such as a polymer or a silica-based low-dielectric material. In a particular embodiment, passivation oxide (not shown, compare FIG. 3, ref. num. 313) is grown on the surface of the silicon wafer when the liner oxide is grown.

In a particular embodiment, the annular silicon oxide rings are formed during the same process steps used to form conventional TSVs. The concentric pockets for the oxide are patterned and etched along with the pocket for the conductor and liner, and silicon oxide is grown to form the concentric oxide rings when the liner oxide is grown. For example, if w1 for the conductor and liner layers is etched to a width of about 8 microns for a liner dielectric thickness of 2.4 microns, the width w2 for the oxide rings is about 4.8 microns. Oxide grows from both walls of the pockets 507, 509 to fill with grown silicon dioxide. The conductor material would fill the remainder of pocket 504, and be about 3.2 microns thick.

FIG. 5D is a cross section of the portion of the silicon wafer of FIG. 5C after a metallization process. Conductive material has been deposited or formed in the remainder of the pocket (see, FIG. 5B, ref. num. 504) to form a conductive portion 514. In a particular embodiment, the conductive portion 514 is formed by sputtering metal, such as copper, on the walls of the pocket and then using a plating technique to fill the remainder of the pocket with metal, such as copper. After the concentric dielectric rings, dielectric liner, and conductive portion have been formed, the backside 516 of the wafer is removed (e.g., backlapped) to expose the lower end of the conductive portion 514 and dielectric portions to form the TSV wafer (compare, FIG. 4B). In a particular embodiment, interposers with TSVs are singulated from the wafer, and ICs are assembled to the interposers.

FIG. 6 is a plan view of a portion of a TSV array 600 according to an embodiment. The TSV array is a portion of a TSV array on an interposer or IC, for example. The TSVs 602, 604 are formed in a silicon wafer 606. Each TSV is a TSA essentially as described in according to an embodiment FIG. 4A and FIG. 4B. The conductor portion 603 of TSV 602 forms a first capacitance C_{sub} with the substrate 606 and forms a second capacitance C_{coupl} with the conductor portion 605 of the TSV 604.

Comparing conventional TSVs 610, 616, the conductor portion 611 is separated from the bulk silicon by the relatively thin liner layer 612, which results in substantially greater capacitive coupling 620 of the conductor portion 611 to the substrate. Similarly, the conventional TSVs 610, 616 also have substantially greater inter-via capacitive coupling 618 between there conductor portions 611, 614.

In TSVs 602, 604 according to an embodiment, the concentric dielectric rings surrounding the conductor (and outer dielectric liner layer, see, e.g., FIG. 4A, ref. nums. 410, 411) reduce both C_{sub} and C_{coupl} compared to a similar conventional TSV, which has a conductor isolated from the substrate by only a dielectric liner layer. The concentric dielectric rings also reduce the capacitance between a contact pad and the substrate in embodiments where the contact pad overlies the concentric dielectric rings. In a particular embodiment both C_{sub} and C_{coupl} are each less than about 50 fF in a silicon substrate having a sheet resistivity of about 20 ohm-cm.

FIG. 7 is a flow chart of a process of fabricating a TSV 700 according to an embodiment. Etch resist is patterned on a silicon wafer to define the TSV having at least one dielectric ring between a dielectric liner layer and the bulk silicon of the silicon wafer (step 702). The TSVs can be fabricated in a silicon interposer wafer or a silicon IC wafer, for example. The silicon wafer is etched to form pockets including a conductor pocket and a dielectric ring pocket (step 704). Oxide is formed on the sidewalls of the conductor pocket to form a liner layer and on the sidewalls of the dielectric ring pocket to fill the dielectric ring pocket and form a dielectric ring (step 706). In a particular embodiment, the oxide is formed using a thermal oxidation process. A conductor is formed in the lined conductor pocket (step 708). In a particular embodiment, the lined conductor pocket is filled with metal, such as copper or a copper alloy. For example, a seed layer of metal is sputtered onto the liner layer of silicon oxide, and a plating process is performed to essentially fill the lined conductor pocket. The resulting conductor is cylindrical (either a hollow metal cylinder or a solid metal cylinder), and the dielectric ring is typically concentric with the conductor. In a further process, the wafer is optionally backlapped (step 710). A contact pad is optionally formed over the conductor and the dielectric ring (step 712).

In a particular embodiment, many TSVs according to one or more embodiments are fabricated concurrently. Embodiments of interposers or ICs optionally include conventional TSVs. For example, a silicon interposer includes TSVs according to one or more embodiments for one or more high-frequency signal or high-speed data paths, and includes conventional TSVs for DC connections. Alternatively, TSVs according to one or more embodiments are used for all TSVs on a silicon interposer. In a further embodiment, a high-speed port or a high-frequency signal port of an IC mounted on a silicon interposer is connected to a TSV according to an embodiment fabricated in the silicon interposer.

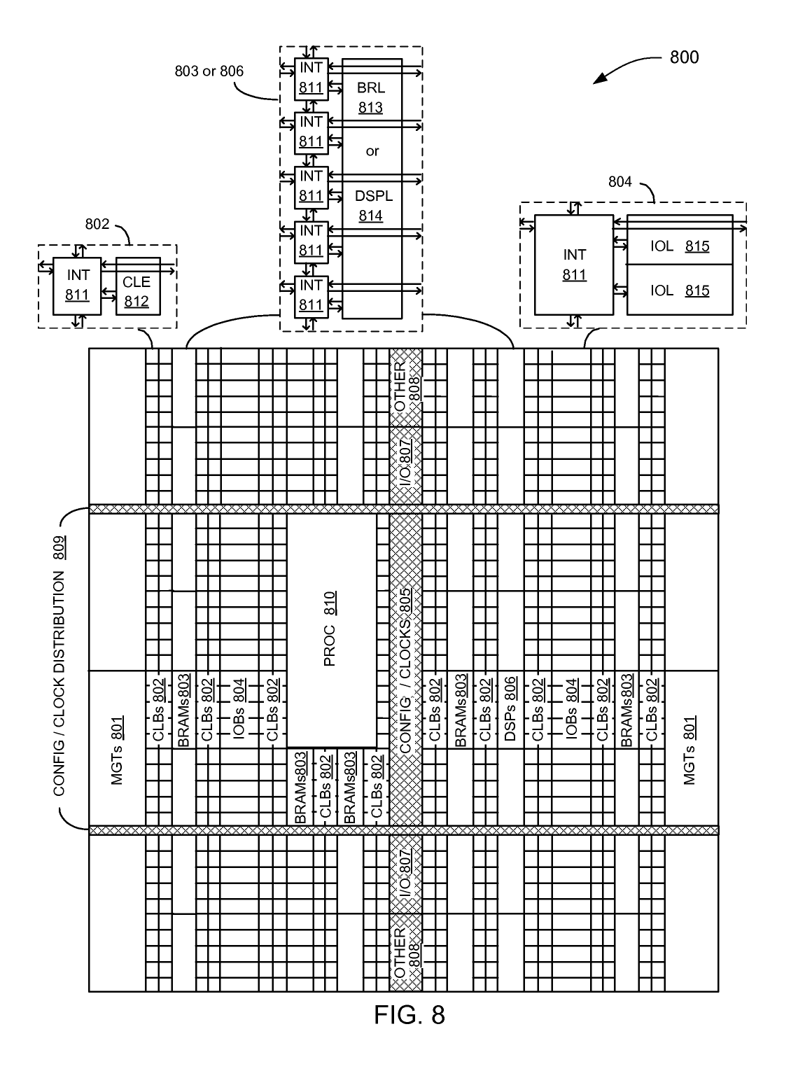

FIG. 8 is a plan view of an FPGA 800 suitable for use with embodiments. The FPGA is fabricated using a CMOS fabrication process or mixed CMOS/NMOS process.

The FPGA architecture includes a large number of different programmable tiles including multi-gigabit transceivers (MGTs) 801, configurable logic blocks (CLBs) 802, random access memory blocks (BRAMs) 803, input/output blocks (IOBs) 804, configuration and clocking logic (CONFIG/CLOCKS) 805, digital signal processing (DSP) blocks 806, specialized input/output blocks (I/O) 807 (e.g., configuration ports and clock ports), and other programmable logic 808 such as digital clock managers, analog-to-digital converters, system monitoring logic, and so forth. Some FPGAs also include dedicated processor blocks (PROC) 810. Horizontal areas 809 extending from the CONFIG/CLOCKS 805 column are used to distribute the clocks and configuration signals across the breadth of the FPGA 800.

In some FPGAs, each programmable tile includes a programmable interconnect element (INT) 811 having standardized connections to and from a corresponding interconnect element in each adjacent tile. Therefore, the programmable interconnect elements taken together implement the programmable interconnect structure for the illustrated FPGA. The programmable interconnect element (INT) 811 also includes the connections to and from the programmable logic element within the same tile, as shown by the examples included at the top of FIG. 8.

For example, a CLB 802 can include a configurable logic element (CLE 812) that can be programmed to implement user logic plus a single programmable interconnect element (INT) 811. A BRAM 803 can include a BRAM logic element (BRL) 813 in addition to one or more programmable interconnect elements. Typically, the number of interconnect elements included in a tile depends on the height of the tile. In the pictured embodiment, a BRAM tile has the same height as five CLBs, but other numbers (e.g., four) can also be used. A DSP tile 806 can include a DSP logic element (DSPL) 814 in addition to an appropriate number of programmable interconnect elements. An IOB 804 can include, for example, two instances of an input/output logic element (IOL) 815 in addition to one instance of the programmable interconnect element (INT) 811. Some FPGAs utilizing the architecture illustrated in FIG. 8 include additional logic blocks that disrupt the regular columnar structure making up a large part of the FPGA. The additional logic blocks can be programmable blocks and/or dedicated logic. For example, the processor block PROC 810 shown in FIG. 8 spans several columns of CLBs and BRAMs. PROC 810 may comprise a single power domain or it may comprise multiple power domains or it may share a power domain with other blocks in FPGA 800.

Note that FIG. 8 is intended to illustrate only an exemplary FPGA architecture. The numbers of logic blocks in a column, the relative widths of the columns, the number and order of columns, the types of logic blocks included in the columns, the relative sizes of the logic blocks, and the interconnect/logic implementations included at the top of FIG. 8 are purely exemplary. For example, in an actual FPGA more than one adjacent column of CLBs is typically included wherever the CLBs appear, to facilitate the efficient implementation of user logic.

While the present invention has been described in connection with specific embodiments, variations of these embodiments will be obvious to those of ordinary skill in the art. For example, alternative dielectric fill material, or additional concentric dielectric rings, or different types of substrates or substrate material could be used, or processing steps could be performed in a different order. Therefore, the spirit and scope of the appended claims should not be limited to the foregoing description.

1. A device, comprising:
a silicon substrate; and
a via extending from a first surface of the silicon substrate having an annular conductive portion,
a first dielectric portion surrounding the annular conductive portion,
a first silicon portion proximate to the first dielectric portion, and
a second dielectric portion disposed between the first silicon portion and the silicon substrate.

2. The device of claim 1, wherein:
the first silicon portion surrounds the first dielectric portion; and
the second dielectric portion surrounds the first silicon portion.

3. The device of claim 1, wherein the via extends from the first surface of the silicon substrate through the silicon substrate to a second surface of the silicon substrate.

4. The device of claim 1, further comprising a contact pad electrically connected to the annular conductive portion and extending over at least the first dielectric portion and the first silicon portion, the second dielectric portion at least partially underlying the contact pad.

5. The device of claim 1, wherein the first dielectric portion is silicon oxide and the second dielectric portion is silicon oxide.

6. The device of claim 1, wherein the first dielectric portion has a first dielectric thickness and the second dielectric portion has a second dielectric thickness, the second dielectric thickness being not greater than twice the first dielectric thickness.

7. The device of claim 1, further comprising a first integrated circuit (IC) mounted on the silicon substrate, the first integrated circuit having a signal pin electrically coupled to the via.

8. The device of claim 7, wherein the IC comprises a field-programmable gate array.

9. The device of claim 7, further comprising a second IC mounted on the silicon substrate.

10. The device of claim 7, further comprising a second IC fabricated in the silicon substrate, the via connecting the signal pin of the first IC to an active portion of the second IC.

11. (canceled)

12. (canceled)

11. (canceled)

12. (canceled)

13. The device of claim 1, wherein the silicon substrate has a bulk resistivity less than 20 Ohm-cm.

14. An interposer, comprising:
a silicon substrate; and
a first via formed in the silicon substrate, the first via having
an annular conductive portion,
a first dielectric liner surrounding the annular conductive portion,
a first silicon portion surrounding the first dielectric liner,
a first dielectric ring surrounding the first silicon portion,
a second silicon portion surrounding the first dielectric ring, and
a second dielectric ring surrounding the second silicon portion.

15. A method of fabricating a via in a silicon wafer, comprising:
defining an etch resist pattern on a surface of the silicon wafer;
etching a conductor pocket and at least one dielectric ring pocket in the silicon wafer separated from the conductor pocket by a silicon portion;
forming oxide on a sidewall of the conductor pocket to provide a lined conductor pocket and on sidewalls of the dielectric ring pocket; and
forming an annular conductive portion in the lined conductor pocket.

16. The method of claim 15, wherein forming oxide on sidewalls of the dielectric ring pocket fills the dielectric ring pocket to form a dielectric ring surrounding the silicon portion.

17. The method of claim 16, further comprising, after the step of forming the annular conductive portion, of backlapping the silicon wafer to expose the annular conductive portion on a backside of the silicon wafer.

18. The method of claim 16, further comprising, after the step of forming the annular conductive portion, forming a contact pad parallel to the surface extending from the annular conductive portion at least partially over the dielectric ring.

19. The method of claim 15, wherein defining the etch resist pattern defines a concentric dielectric ring window around a conductor window, the concentric dielectric ring window having a width not greater than twice a thickness of oxide formed on the sidewall of the conductor pocket.

20. The method of claim 19, wherein:
defining the etch resist pattern further defines a second concentric dielectric ring window around the concentric dielectric ring window; and
the etching leaves a first concentric silicon portion between the conductor pocket and the concentric dielectric ring pocket and a second concentric silicon portion between the concentric dielectric ring pocket and a second concentric dielectric ring pocket.

21. The device of claim 10, wherein the second IC comprises a field-programmable gate array.

22. The device of claim 10, wherein the second IC has a second signal pin electrically connected to a second via having
a second conductor portion,
a dielectric liner portion surrounding the second conductor portion,
a first floating silicon portion, and
a dielectric ring surrounding the first floating silicon portion disposed between the first floating silicon portion and the silicon substrate.

23. The device of claim 1, further comprising
a second silicon portion surrounding the second dielectric portion; and
a third dielectric portion surrounding the second silicon portion.

24. The device of claim 23, wherein the silicon substrate is a silicon interposer and wherein a capacitance between the annular conductive portion and the silicon substrate is not greater than 50 fF.
